(19) United States
(12) Patent Application Publication
(10) Pub. No.: US 2020/0168538 A1
(43) Pub. Date: May 28, 2020

(54) MULTIPLE-SURFACE CONNECTED EMBEDDED INTERCONNECT BRIDGE FOR SEMICONDUCTOR PACKAGE SUBSTRATES

(71) Applicant: Intel Corporation, Santa Clara, CA (US)

(72) Inventors: Jenny Shio Yin Ong, Bayan Lepas (MY); Seok Ling Lim, Kulim (MY); Bok Eng Cheah, BUKIT GAMBIR (MY); Jackson Chung Peng Kong, Tanjung Tokong, (MY)

(21) Appl. No.: 16/662,990

(22) Filed: Oct. 24, 2019

(30) Foreign Application Priority Data
Nov. 27, 2018 (MY) PI2018002144

(51) Int. Cl. H01L 23/498; H01L 23/495; H01L 23/48; H01L 23/522; H01L 23/00

(52) U.S. Cl. CPC H01L 23/49827; H01L 23/49531; H01L 24/13; H01L 23/5227; H01L 23/481

(57) ABSTRACT

An embedded interconnect bridge includes a backside trace that can be coupled to a power plane within a semiconductor package substrate. The embedded interconnect bridge-backside trace preserves useful package real estate that is near to where multiple dice are to be mounted on the semiconductor package substrate.

### PRIORITY APPLICATION

This application claims the benefit of priority to Malaysian Application Serial Number PI 2018002144, filed Nov. 27, 2018, which is incorporated herein by reference in its entirety.

### FIELD

This disclosure relates to power delivery and preserving dense printed wiring board with an embedded interconnect bridge.

### BACKGROUND

Semiconductive device miniaturization during packaging includes challenges to meet wiring-trace density requirements for high bandwidth device-to-device interconnects.

### BRIEF DESCRIPTION OF THE DRAWINGS

Disclosed embodiments are illustrated by way of example, and not by way of limitation, in the figures of the accompanying drawings where like reference numerals may refer to similar elements, in which:

FIG. 1 is a schematic cross-section elevation of an embedded-bridge semiconductor device package according to an embodiment;

FIG. 2 is a schematic cross-section elevation and detail section of the embedded-bridge semiconductor device package depicted in FIG. 1 according to an embodiment;

FIG. 3 is a bottom plan cut-away of a portion of the embedded multiple-die interconnect bridge depicted in FIGS. 1 and 2 according to an embodiment;

FIG. 4 is a perspective elevation of an embedded multiple-die interconnect bridge such as the embedded multiple-die interconnect bridge depicted in FIGS. 1 and 2 according to an embodiment;

FIG. 5 is a schematic cross-section elevation of an embedded-bridge semiconductor device package according to an embodiment;

FIG. 6 is a schematic cross-section elevation and detail section of the embedded-bridge semiconductor device package depicted in FIG. 5 according to an embodiment;

FIG. 7A is a cross-section elevation of an embedded interconnect bridge during fabrication and assembly according to an embodiment;

FIG. 7B is a cross-section elevation of the embedded interconnect bridge depicted in FIG. 7A after further processing according to an embodiment;

FIG. 7C is a cross-section elevation of the embedded interconnect bridge depicted in FIG. 7B after further processing according to an embodiment

FIG. 7D is a cross-section elevation of the embedded interconnect bridge depicted in FIG. 7C after further processing according to an embodiment;

FIG. 7E is a cross-section elevation of the embedded interconnect bridge depicted in FIG. 7D after further processing according to an embodiment;

FIG. 7F is a cross-section elevation of the embedded interconnect bridge depicted in FIG. 7E after further processing according to an embodiment;

FIG. 7G is a cross-section elevation of the embedded interconnect bridge depicted in FIG. 7F after further assembly according to an embodiment;

FIG. 8A is a cross-section elevation of an embedded interconnect bridge with an auxiliary bridge during fabrication and assembly according to an embodiment;

FIG. 8B is a cross-section elevation of the embedded interconnect bridge depicted in FIG. 8A after further processing according to an embodiment;

FIG. 8C is a cross-section elevation of the embedded interconnect bridge depicted in FIG. 8B after further processing according to an embodiment;

FIG. 8D is a cross-section elevation of the embedded interconnect bridge depicted in FIG. 8C after further processing according to an embodiment;

FIG. 8E is a cross-section elevation of the embedded interconnect bridge depicted in FIG. 8D after further processing according to an embodiment;

FIG. 8F is a cross-section elevation of the embedded interconnect bridge depicted in FIG. 8E after further processing according to an embodiment;

FIG. 8G is a cross-section elevation of the embedded interconnect bridge depicted in FIG. 8F after further processing according to an embodiment;

FIG. 8H is a cross-section elevation of the embedded interconnect bridge depicted in FIG. 8G after further assembly according to an embodiment;

FIG. 9 is a process flow diagram 900 according to an embodiment; and

FIG. 10 is included to show an example of a higher-level device application for the disclosed embodiments.

### DETAILED DESCRIPTION

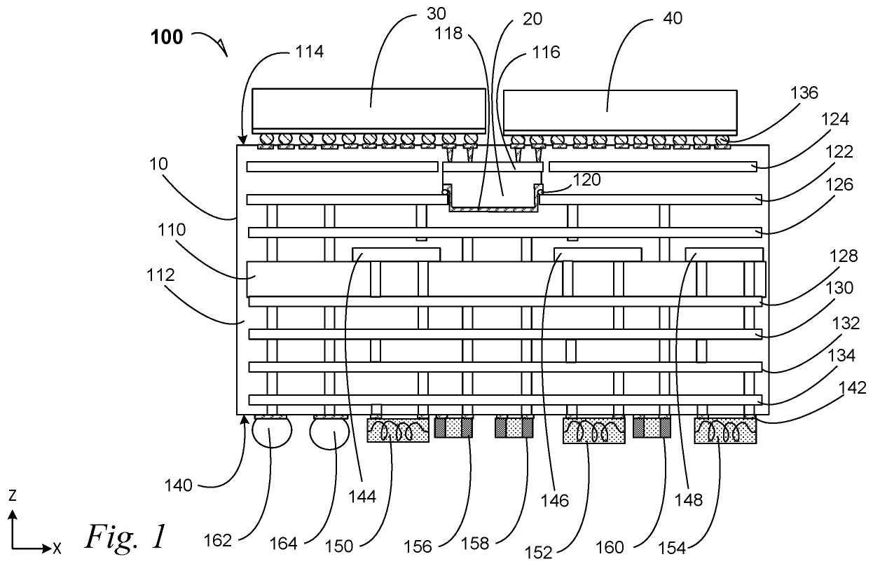

FIG. 1 is a schematic cross-section elevation of an embedded-bridge semiconductor device package 100 according to an embodiment. Several structures including conductive planes, traces and vias are schematically depicted in projection from the drawing, and where they appear to cross, they do not necessarily make contact.

A semiconductor package substrate 10 includes a substrate core 110 and several layers of interlayer dielectric (ILD), which are illustrated without detail at 112. An embedded multi-die interconnect bridge (EMIB) 20 is located within the semiconductor package substrate 10 between a die side 114 and the substrate core 110. In an embodiment, the EMIB 20 is semiconductive material including the bulk being a semiconductive substrate, and it may be referred to as a bridge die 20. In an embodiment, the EMIB 20 includes a metallization layer 116 on a first surface. In and embodiment, the metallization layer 116 includes active devices and metallization 116 on the first surface. In an embodiment, the EMIB 20 also includes an EMIB-backside power trace 118 on a backside surface. In an embodiment, the EMIB-backside power trace 118 includes a power plane 118. The EMIB-backside power trace 118 may also be referred to as a trace on the backside of the EMIB 20. In an embodiment, the EMIB-backside power trace 118 is a metal such as plated copper-containing material 118. The EMIB-backside power trace 118 is coupled through an electrical bump 120 to a power plane 122, such as may be referred to as a VCCIN power plane 122 at a level that may be referred to as the third front (3F) level within the semiconductor package substrate 10.

As depicted, the semiconductor package substrate 10 includes the power plane 122, an EMIB-level source (4F VSS) trace and/or plane 124, and a penultimate front source (2F VSS) trace and/or plane 126. Below the substrate core 110 are included a VCCIN power plane 128 which may be referred to as 1BC0 where BC0 stands for backside-core level zero, a source trace and/or plane (2B VSS) 130, a power plane (3B VCCIN) 132, and a source trace and/or plane (4B VSS) 134.

In an embodiment, the semiconductor package substrate 10 supports a first semiconductive device 30 and a subsequent semiconductive device 40 on the die side 114, and an electrical bump array contacts the die side 114 and the first and subsequent semiconductive devices 30 and 40, one electrical bump of which is indicated with reference number 136. Contacts in an embodiment for the semiconductor package substrate 10 on a land side 140 include bond pads, one bond pad of which is indicated with reference number 142.

In an embodiment, inductor coils 144, 146 and 148 are embedded in the semiconductor package substrate 10. In an embodiment, the embedded inductor coils 144, 146 and 148 include a plurality stacked of metal traces (e.g., routed in helical form), extending through the substrate core 110 to the land side 140. In an embodiment, the plurality stacked of metal traces are interconnected through a plurality of micro-vias and connected to inductors 150, 152 and 154 on the land side 140. In an embodiment, the inductors 150, 152 and 154 include magnetic inductor arrays (MIAs). In an embodiment, other passive devices such as capacitors 156, 158 and 160 are located on the land side 140. Connection to a printed wiring board such as a mother board is accomplished by an electrical bump array, two electrical bumps of which are indicated by reference numbers 162 and 164. In an embodiment, the electrical bump array 162 and 164 includes more than two rows and the array extends around the periphery of the semiconductor package substrate 10.

By locating the EMIB-backside power trace 118 below and across the EMIB 20, useful package-wiring real estate is preserved below the EMIB 20, for power delivery and useful low-inductance loops that service the respective first and subsequent semiconductive devices 30 and 40 on the die side 114 of the semiconductor package substrate 10.

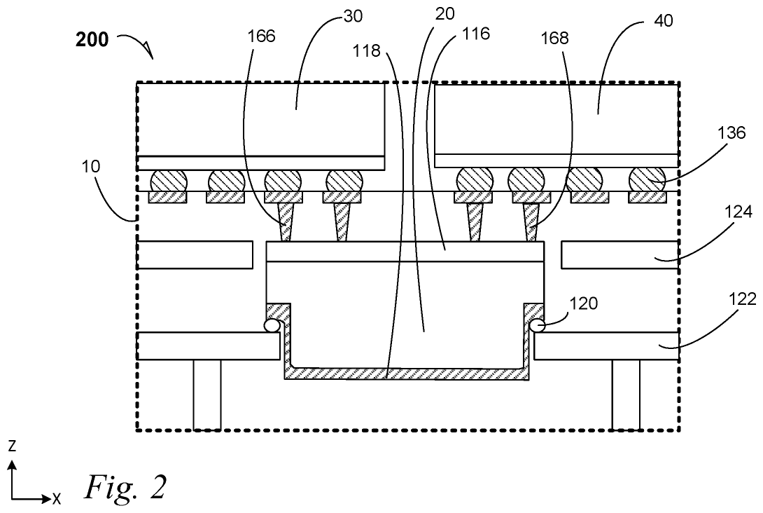

FIG. 2 is a schematic cross-section elevation and detail section 200 of the embedded-bridge semiconductor device package 100 depicted in FIG. 1 according to an embodiment. Several structures including planes, traces and vias are schematically depicted in projection from the drawing, and where they appear to cross, they do not necessarily make contact.

The semiconductor package substrate 10 encloses the embedded multi-die interconnect bridge (EMIB) 20 where the metallization layer 116 contacts vias, one via of which is indicated with reference number 166 and which is coupled to the first semiconductive device 30, and a via 168 which is coupled to the subsequent semiconductive device 40. The via 166 may be referred to as a first interconnect via 166, and the via 168 may be referred to as a subsequent interconnect via 168. Each via 166 and 168, contact the metallization layer 116. In an embodiment, the metallization layer 116 comprises one or more metal layer stack that includes a fine-pitch signal routing, a ground (Vss) reference routing and a power (Vcc) routing. The metal routing and the metal layer stack in the metallization layer 116 are electrically isolated by a dielectric layer e.g., a passivation layer or a polyimide layer. The EMIB-backside power trace 118 is coupled through the electrical bump 120 to the power plane 122, such as may be referred to as a VCCIN power plane 122 at a level such as may be referred to as the third front (3F) level within the semiconductor package substrate 10.

FIG. 3 is a bottom plan cut-away 300 of a portion of the EMIB 20 depicted in FIGS. 1 and 2 according to an embodiment. The EMIB 20 has the EMIB-backside power trace 118 that is seen in the X-Z illustrations depicted in FIGS. 1 and 2. Further in an embodiment, an EMIB-backside power trace 119 is adjacent the EMIB-backside power trace 118 as illustrated in the X-Y layout as illustrated. In an embodiment, the EMIB-backside power trace 118 is used for a VCC1 potential of 1.0 Volt, and the EMIB-backside power trace 119 is used for a VCC2 potential of 1.5 Volt. To accommodate the EMIB-backside power traces 118 and 119, a power plane 122 such as the power plane 122 depicted in FIGS. 1 and 2 contacts the EMIB-backside power trace 118, and a power plane 125 contacts the EMIB-backside power trace 119. In an embodiment, the power planes 122 and 125, or one of them, is a power-rail form factor. The rails 122 and 125 continue on the other side of the EMIB 20 as 122′ and 125′, respectively.

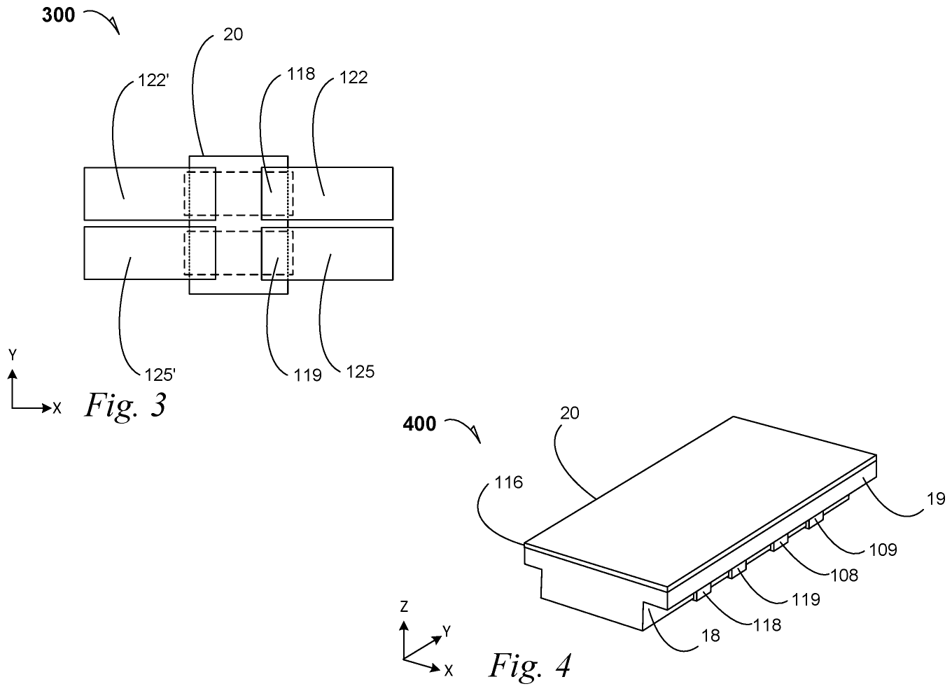

FIG. 4 is a perspective elevation 400 of an EMIB 20 such as the EMIB 20 depicted in FIGS. 1 and 2 according to an embodiment. In an embodiment, metallization layer 116 tops the EMIB 20, and a ridge 19 accommodates a portion of the EMIB-backside power trace 118 on a sidewall 18 of the EMIB 20. As illustrated, the EMIB-backside power 118 trace also contacts the EMIB adjacent the ridge 19. In an embodiment, the EMIB-backside power trace 118 is accompanied by an adjacent EMIB-backside power trace 119 on the ridge 19, as well as on the bottom of the EMIB 20, as seen in FIGS. 1 and 2.

In an embodiment, an EMIB-backside ground (Vss) trace 108 is on the ridge 19 (obscured), as well as on the sidewall 18 and the bottom of the EMIB 20, as seen in FIGS. 1 and 2. In an embodiment, an EMIB-backside signal trace 109 is on the ridge 19 (obscured), as well as on the sidewall 18 and the bottom of the EMIB 20, as seen in FIGS. 1 and 2.

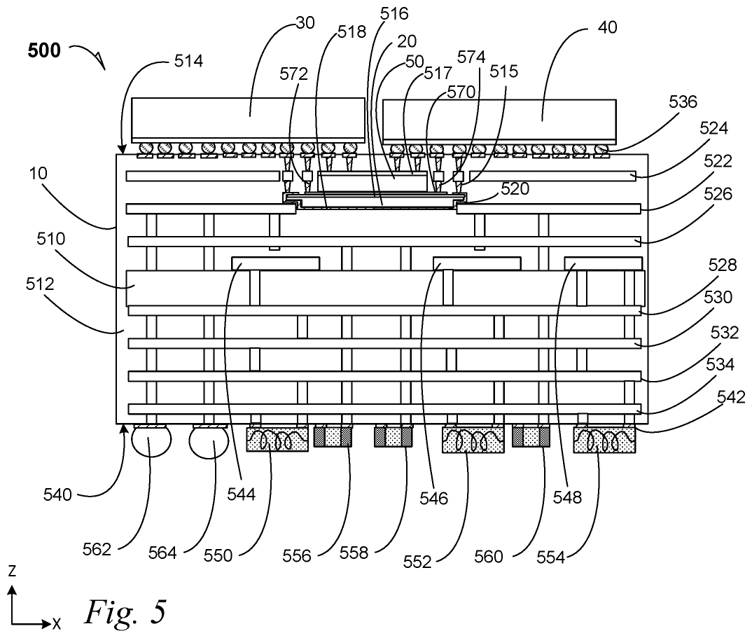

FIG. 5 is a schematic cross-section elevation of an embedded-bridge semiconductor device package 500 according to an embodiment. Several structures including conductive planes, traces and vias are schematically depicted in projection from the drawing, and where they appear to cross, they do not necessarily make contact.

A semiconductor package substrate 10 includes a substrate core 510 and several layers of interlayer dielectric (ILD), which are illustrated without detail at 512. An embedded multi-die interconnect bridge (EMIB) 20 is located within the semiconductor package substrate 10 between a die side 514 and the substrate core 510. In an embodiment, the EMIB 20 includes a metallization layer 516. In an embodiment, the metallization layer 516 includes a conductive plane associated with a reference voltage e.g., a ground (Vss) reference voltage. In an embodiment, the metallization layer 516 comprises one or more metal layer stack that includes a fine-pitch signal routing, a ground (Vss) reference routing and a power (Vcc) routing. The metal routing and the metal layer stack in the metallization layer 516 are electrically isolated by a dielectric layer e.g., a passivation layer or a polyimide layer. In an embodiment, the metallization layer 516 includes active devices and metallization 516. In an embodiment, the EMIB 20 also includes an EMIB-backside power trace 518 such as plated copper-containing material 518. The EMIB-backside power trace 518 is coupled through an electrical bump 520 to a power plane 522, such as may be referred to as a VCCIN power plane 522 at a level that may be referred to as the third front (3F) level within the semiconductor package substrate 10.

As illustrated, the EMIB-backside power trace 518 also contacts the ridge, as well as the first surface. As illustrated, the EMIB power trace 518 also is on the first surface of the EMIB 20, and it is contacted by a via 515 that can supply power to the subsequent semiconductive device 40. In an embodiment, the EMIB-backside power trace 518 on the first surface of the EMIB 20 is electrically isolated from the metallization layer 516 through a dielectric layer e.g., a passivation layer or a polyimide layer. In an embodiment, X-Y footprint of the metallization layer 516 is a subset of the X-Y footprint of the first surface of the EMIB 20. In an embodiment, the metallization layer 516 has an X-Y footprint ranging 0.6× to 0.8× of the X-Y footprint of the first surface of the EMIB 20.

In an embodiment, a subsequent EMIB 50 is seated on the EMIB 20 and above the metallization 516. In an embodiment, the subsequent EMIB 50 has an X-Y footprint smaller than the EMIB 20. In an embodiment, the subsequent EMIB 50 has an EMIB metallization 517. In an embodiment, the metallization layer 517 comprises one or more metal layer stack that includes a fine-pitch signal routing, a ground (Vss) reference routing and a power (Vcc) routing, similar to the metallization 116. In an embodiment, an inter-EMIB adhesion layer 570 acts as a mechanical protection layer for the stacked EMIB. The subsequent EMIB 50 may also be referred to as a stacked bridge 50 as it is on the first EMIB 20. The subsequent EMIB 50 may also be referred to as a subsequent bridge device 50 where the semiconductive device 20 may be referred to as a first bridge device 20.

As depicted, the semiconductor package substrate 10 includes the power plane 522, an EMIB-level source (4F VSS) trace and/or plane 524, and a penultimate front source (2F VSS) trace and/or plane 526. Below the substrate core 510 are included a VCCIN power plane 528 which may be referred to as 1BC0 where BC0 stands for backside-core level zero, a source trace and/or plane (2B VSS) 530, a power plane (3B VCCIN) 532, and a source trace and/or plane (4B VSS) 534.

In an embodiment, the semiconductor package substrate 10 supports the first semiconductive device 30 and the subsequent semiconductive device 40 on the die side 514, and an electrical bump array contacts the die side 514 and the first and subsequent semiconductive devices 30 and 40, one electrical bump of which is indicated with reference number 536. Contacts in an embodiment for the semiconductor package substrate 10 on a land side 540 include bond pads, one bond pad of which is indicated with reference number 542.

In an embodiment, inductor coils 544, 546 and 548 are embedded in the semiconductor package substrate 10. In an embodiment, the embedded inductor coils 544, 546 and 548 include a plurality stacked of metal traces (e.g., routed in cyclical form), extending from the substrate core 510 to the land side 540. In an embodiment, the plurality stacked of metal traces are interconnected through a plurality of micro-vias and connected to inductors 550, 552 and 554 on the land side 540. In an embodiment, the inductors 550, 552 and 554 include magnetic inductor arrays (MIAs). In an embodiment, other passive devices such as capacitors 556, 558 and 560 are located on the land side 540. Connection to a printed wiring board such as a mother board is accomplished by an electrical bump array, two electrical bumps of which are indicated by reference numbers 562 and 564. In an embodiment, the electrical bump array 562 and 564 includes more than two rows and the array extends around the periphery of the semiconductor package substrate 10.

By locating the EMIB-backside power trace 518 below and across the first EMIB 20, useful package-wiring real estate is preserved below the EMIB 20, for power delivery and useful low-inductance loops that service the respective first and semiconductive devices 30 and 40 on the die side 514 of the semiconductor package substrate 10. By seating the subsequent EMIB 50 on the first EMIB 20, further power-delivery and signal layout, increases interconnect routing density between the first and subsequent semiconductive device 30 and 40 on the die side 514 of the semiconductor package substrate 10.

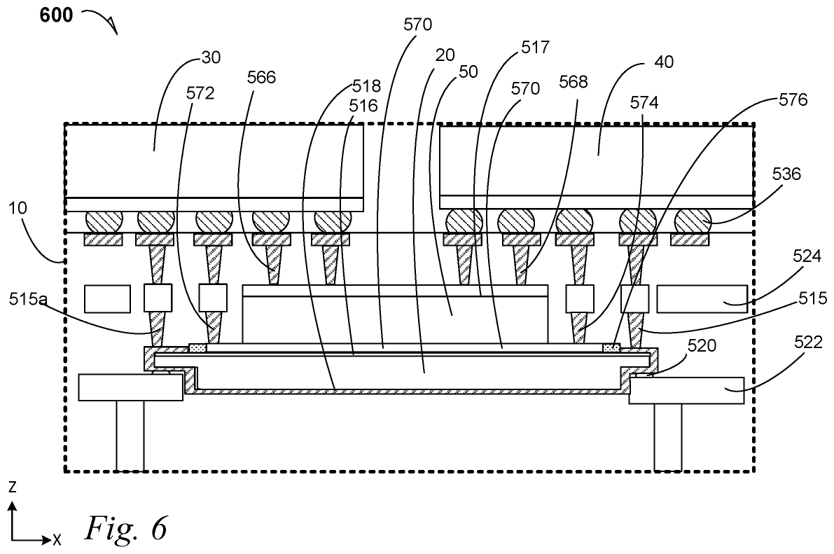

FIG. 6 is a schematic cross-section elevation and detail section 600 of the embedded-bridge semiconductor device package 500 depicted in FIG. 5 according to an embodiment. Several structures including planes, traces and vias are schematically depicted in projection from the drawing, and where they appear to cross, they do not necessarily make contact.

The semiconductor package substrate 10 encloses the embedded multi-die interconnect bridge (EMIB) 20 where the metallization layer 516 contacts vias, one via of which is indicated with reference number 572 and which contacts the first semiconductive device 30, and a via 572 which contacts the subsequent semiconductive device 40. In an embodiment, the metallization layer 516 includes a conductive plane associated with a reference voltage e.g., a ground (Vss) reference voltage. In an embodiment, the metallization layer 516 comprises one or more metal layer stack that includes a fine-pitch signal routing, a ground (Vss) reference routing and a power (Vcc) routing. The metal routing and the metal layer stack in the metallization layer 516 are electrically isolated by a dielectric layer e.g., a passivation layer or a polyimide layer. The EMIB-backside power trace 518 is coupled through the electrical bump 520 to the power plane 522, such as may be referred to as a VCCIN power plane 522 at a level such as may be referred to as the third front (3F) level within the semiconductor package substrate 10. In an embodiment, vias 515 and 515a are in contact with the EMIB power trace 518 on the first surface of the EMIB 20 to reduce the inductance loop between the first and subsequent semiconductive device 30 and 40. In an embodiment, the EMIB-backside power trace 518 on the first surface of the EMIB 20 is electrically isolated from the metallization layer 516 through a dielectric layer 576.

In an embodiment, the inter-EMIB adhesion layer 570 is disposed between the first bridge device 20 and the subsequent bridge device 50 to provide mechanical protection to the first bridge device 20.

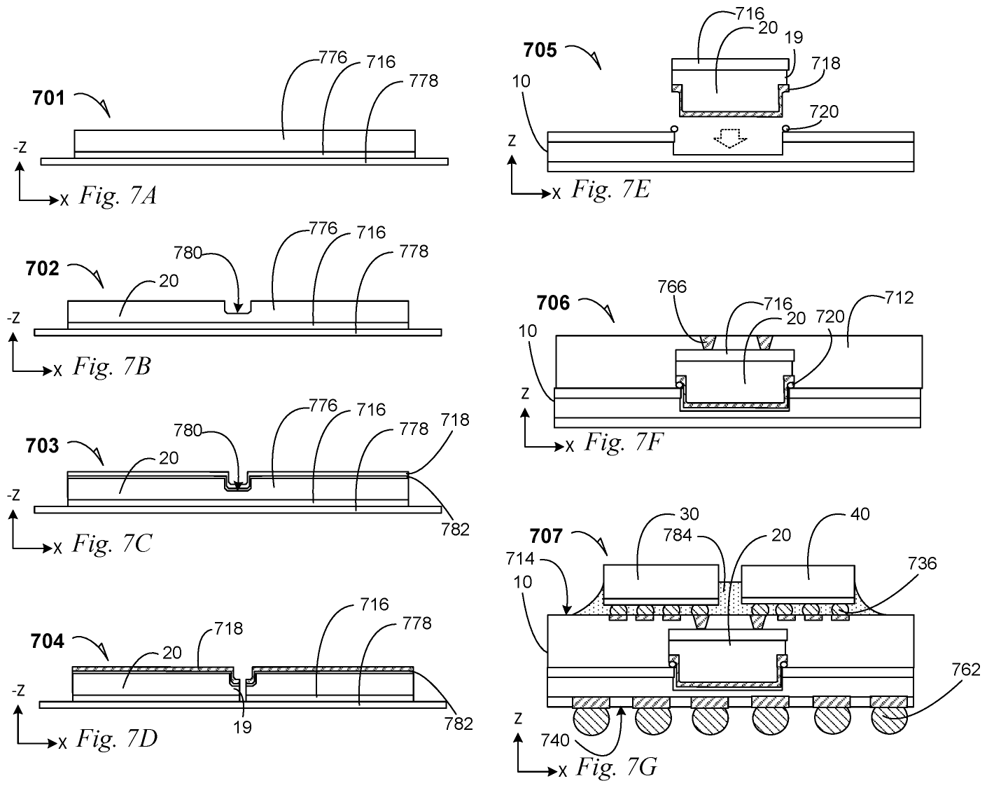

FIG. 7A is a cross-section elevation of an embedded interconnect bridge 701 during fabrication and assembly according to an embodiment. An EMIB wafer 776 is seated on a carrier 778, and the EMIB wafer 776 includes at least wafer-level metallization 716 that will be preserved after singulation.

FIG. 7B is a cross-section elevation of the embedded interconnect bridge 701 depicted in FIG. 7A after further processing according to an embodiment. A recess 780 is formed in the embedded interconnect bridge 702 to begin definition and singulation of a first EMIB 20. In an embodiment, a mechanical drill is used to form the recess 780. In an embodiment, an ultraviolet drill is used to form the recess 780. In an embodiment, an laser drill is used to form the recess 780.

FIG. 7C is a cross-section elevation of the embedded interconnect bridge 702 depicted in FIG. 7B after further processing according to an embodiment. A seed layer 782 is electrolessly patterned and plated on the EMIB wafer 776, and an EMIB-backside power trace 718 is electroplated to the seed layer 782. In an embodiment, the EMIB-backside power trace 718 comprises a metal e.g., copper-containing. In an embodiment, the EMIB-backside power trace 718 comprises a metal e.g., aluminum-containing. In an embodiment, the EMIB-backside power trace 718 is a solder material.

FIG. 7D is a cross-section elevation of the embedded interconnect bridge 703 depicted in FIG. 7C after further processing according to an embodiment. The recess 780 depicted in FIG. 7C has been further cut through to expose the carrier 778, such as by a mechanical saw, to achieve singulation of the EMIB 20, and to create a ridge 19 similar to the ridge 19 depicted in FIG. 4. The EMIB-backside power trace 718 is both on the EMIB backside as well as on the ridge 19.

FIG. 7E is a cross-section elevation of the embedded interconnect bridge 704 depicted in FIG. 7D after further processing according to an embodiment. A singulated EMIB 20 is being seated into a semiconductor package substrate 10, where the EMIB-backside power trace 718 is both on the EMIB backside and adjacent below the ridge 19. An electrical bump 720 will contact the EMIB-backside power trace 718 when seating is completed. For example a thermo-compression technique is used, both to seat the EMIB 20, and to reflow the electrical bump 720 adjacent and below the ridge 19 into the EMIB-backside power trace 718. In an embodiment, the electrical bump 720 includes solder paste material. In an embodiment, the electrical bump 720 is optional such as when the EMIB-backside power trace 718 is electroplated with a solder composite material.

FIG. 7F is a cross-section elevation of the embedded interconnect bridge 705 depicted in FIG. 7E after further processing according to an embodiment. A dielectric material 712 is formed over the EMIB 20, planarization is carried out, and the metallization layer 716 is contacted through the dielectric material 712 by an interconnect via 766.

FIG. 7G is a cross-section elevation of the embedded interconnect bridge 706 depicted in FIG. 7F after further assembly according to an embodiment. A first semiconductive device 30 and a subsequent semiconductive device 40 are seated on a die side 714 of the semiconductor package substrate 10, and the devices are coupled to the EMIB 20 through an electrical bump array 736. Further a land-side bump array 762 is formed on the semiconductor package substrate 10 on a land side 740 to contact a board such as a motherboard. Processing techniques include surface-mounting the semiconductive devices 30 and 40, and an underfill material 784 encloses the active layers of the semiconductive devices 30 and 40.

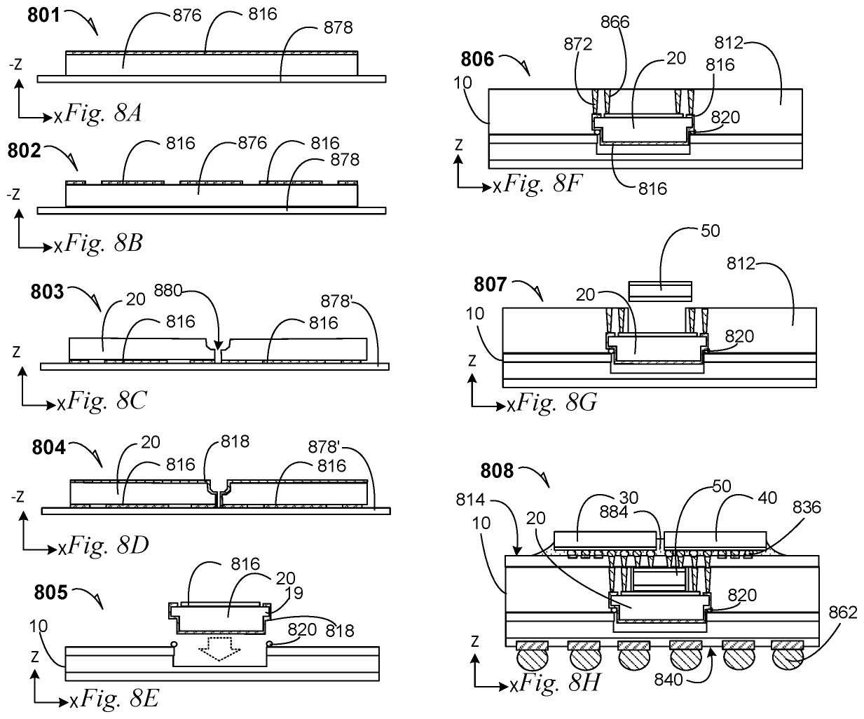

FIG. 8A is a cross-section elevation of an embedded interconnect bridge with an auxiliary bridge 801 during fabrication and assembly according to an embodiment. An EMIB wafer 876 is seated on a carrier 878, and the EMIB wafer 876 includes at least a conductive layer 816 that will be patterned. In an embodiment, the conductive layer 816 comprises a plurality of metal layers with signal routing and/or metal planes e.g., a ground (Vss) plane or a power (Vcc) power plane.

FIG. 8B is a cross-section elevation of the embedded interconnect bridge 802 after further processing according to an embodiment. The conductive layer 816 has been patterned, such as by etching through a mask, and removing the mask.

FIG. 8C is a cross-section elevation of the interconnect bridge 803 after further processing according to an embodiment. A recess 880 is formed in the embedded interconnect bridge 803 to begin definition and singulation of a first EMIB 20. In an embodiment, a mechanical drill is used to form the recess 880, followed by a saw. The wafer 816 has been released from the carrier 878, seen in FIG. 8A, the wafer 876 has been inverted and seated by the patterned conductive layer 816 onto a subsequent carrier 878′.

FIG. 8D is a cross-section elevation of the embedded interconnect bridge 804 after further processing according to an embodiment. An EMIB-backside power trace 818 is plated onto the EMIB 20 opposite the patterned conductive layer 816. In an embodiment, the EMIB-backside power trace 818 is a solder material.

FIG. 8E is a cross-section elevation of an embedded interconnect bridge 805 after further processing according to an embodiment. The singulation of the EMIB 20, and to creates a ridge 19 similar to the ridge 19 depicted in FIG. 4. The EMIB-backside power trace 818 is both on the EMIB backside as well as on the ridge 19, and the trace 818 has contacted a portion of the patterned conductive layer 816, such that the trace 818 effectively is also on the first surface of the bridge die 20. A singulated EMIB 20 is being seated into a semiconductor package substrate 10, where the EMIB-backside power trace 818 is both on the EMIB backside and the ridge 19. An electrical bump 820 will contact the EMIB-backside power trace 818 when seating is completed. For example, a thermo-compression technique is used, both to seat the EMIB 20, and to reflow the electrical bump 820 at the ridge 19 of the EMIB-backside power trace 818.

FIG. 8F is a cross-section elevation of an embedded interconnect bridge 806 after further processing according to an embodiment. A dielectric material 812 is formed over the EMIB 20, planarization is carried out, and the metallization layer 816 is contacted through the dielectric material 812 by an interconnect via 866 that contacts the patterned metallization layer, and by a via 872 that contacts the EMIB-backside power trace 818. As noted, the indicated patterned metallization layer portion 816 contacts the trace 818 to effectively make the trace 818 to be also on the first side of the bridge die 20.

FIG. 8G is a cross-section elevation of an embedded interconnect bridge 807 after further processing according to an embodiment. A subsequent EMIB 50 is seated into a recess in the dielectric material 812, at the level of the vias 866 and 872. The subsequent EMIB 50 may be referred to as a stacked bridge die 50. In an embodiment, the subsequent EMIB 50 is seated on the first side of the bridge die 20 prior to the formation of the dielectric layer 812 over the bridge die 20 and the formation of the interconnect vias 866 and 872.

FIG. 8H is a cross-section elevation of an embedded interconnect bridge 808 after further assembly according to an embodiment. A first semiconductive device 30 and a subsequent semiconductive device 40 are seated on a die side 814 of the semiconductor package substrate 10, and the devices are coupled to the EMIB 20 through an electrical bump array 836. Further a land-side bump array 862 is formed on the semiconductor package substrate 10 on a land side 840. Processing techniques include surface-mounting the semiconductive devices 30 and 40, and an underfill material 884 encloses the active layers of the semiconductive devices 30 and 40. The first EMIB 20 and the subsequent EMIB 50 are coupled to power, ground and signal vias.

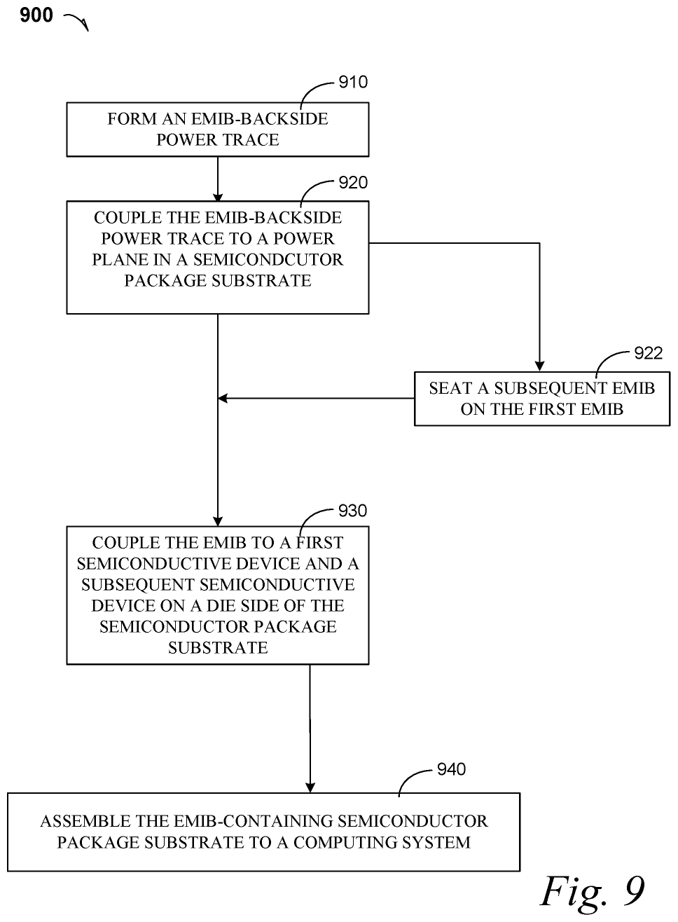

FIG. 9 is a process flow diagram 900 according to an embodiment.

At 910, the process includes forming an EMIB-backside power trace.

At 920, the process includes coupling the EMIB-backside power trace to a power plane in a semiconductor package substrate.

At 922, the process includes seating a subsequent EMIB on the first EMIB.

At 930, the process includes coupling the EMIB to a first semiconductive device and to a subsequent semiconductive device on a die side of the semiconductor package

At 940, the process includes assembling the EMIB-backside trace containing EMIB to a computing system.

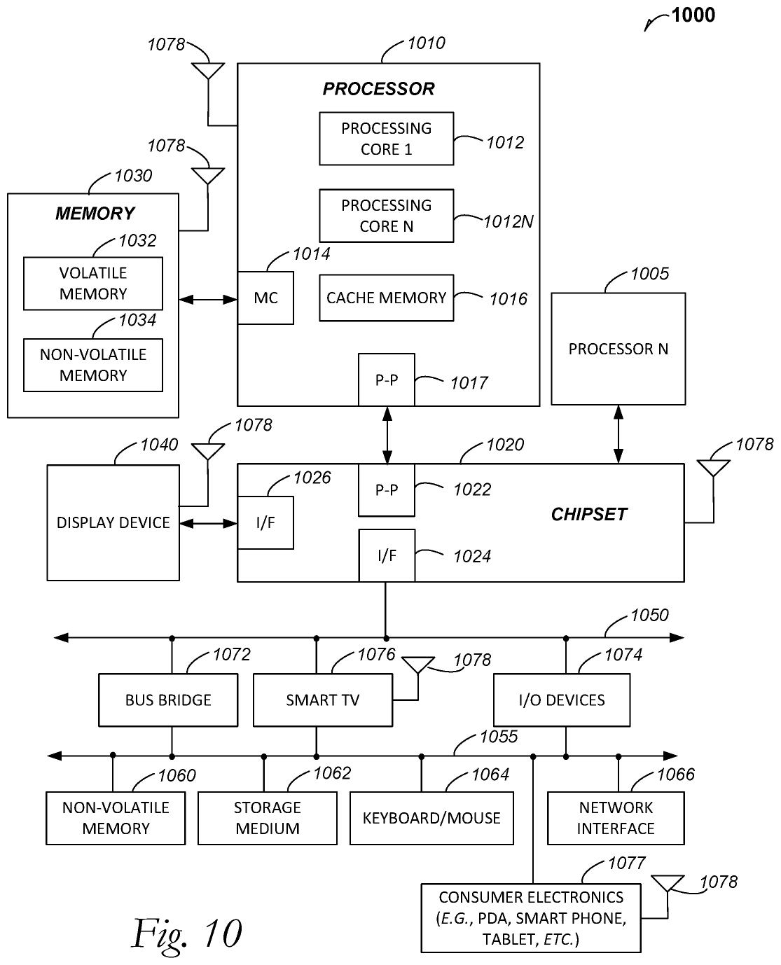

FIG. 10 is included to show an example of a higher-level device application for the disclosed embodiments. The EMIB-backside trace containing embodiments may be found in several parts of a computing system. In an embodiment, the EMIB-backside trace containing embodiments can be part of a communications apparatus such as is affixed to a cellular communications tower. In an embodiment, a computing system 1000 includes, but is not limited to, a desktop computer. In an embodiment, a system 1000 includes, but is not limited to a laptop computer. In an embodiment, a system 1000 includes, but is not limited to a tablet. In an embodiment, a system 1000 includes, but is not limited to a notebook computer. In an embodiment, a system 1000 includes, but is not limited to a personal digital assistant (PDA). In an embodiment, a system 1000 includes, but is not limited to a server. In an embodiment, a system 1000 includes, but is not limited to a workstation. In an embodiment, a system 1000 includes, but is not limited to a cellular telephone. In an embodiment, a system 1000 includes, but is not limited to a mobile computing device. In an embodiment, a system 1000 includes, but is not limited to a smart phone. In an embodiment, a system 1000 includes, but is not limited to an internet appliance. Other types of computing devices may be configured with the microelectronic device that includes EMIB-backside trace containing embodiments.

In an embodiment, the processor 1010 has one or more processing cores 1012 and 1012N, where 1012N represents the Nth processor core inside processor 1010 where N is a positive integer. In an embodiment, the electronic device system 1000 using a EMIB-backside trace containing embodiment that includes multiple processors including 1010 and 1005, where the processor 1005 has logic similar or identical to the logic of the processor 1010. In an embodiment, the processing core 1012 includes, but is not limited to, pre-fetch logic to fetch instructions, decode logic to decode the instructions, execution logic to execute instructions and the like. In an embodiment, the processor 1010 has a cache memory 1016 to cache at least one of instructions and data for the EMIB-backside trace containing embodiment in the system 1000. The cache memory 1016 may be organized into a hierarchal structure including one or more levels of cache memory.

In an embodiment, the processor 1010 includes a memory controller 1014, which is operable to perform functions that enable the processor 1010 to access and communicate with memory 1030 that includes at least one of a volatile memory 1032 and a non-volatile memory 1034. In an embodiment, the processor 1010 is coupled with memory 1030 and chipset 1020. In an embodiment, the chipset 1020 is part of a EMIB-backside trace containing embodiment depicted in FIG. 2. The processor 1010 may also be coupled to a wireless antenna 1078 to communicate with any device configured to at least one of transmit and receive wireless signals. In an embodiment, the wireless antenna interface 1078 operates in accordance with, but is not limited to, the IEEE 802.11 standard and its related family, Home Plug AV (HPAV), Ultra Wide Band (UWB), Bluetooth, WiMax, or any form of wireless communication protocol.

In an embodiment, the volatile memory 1032 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. The non-volatile memory 1034 includes, but is not limited to, flash memory, phase change memory (PCM), read-only memory (ROM), electrically erasable programmable read-only memory (EEPROM), or any other type of non-volatile memory device.

The memory 1030 stores information and instructions to be executed by the processor 1010. In an embodiment, the memory 1030 may also store temporary variables or other intermediate information while the processor 1010 is executing instructions. In the illustrated embodiment, the chipset 1020 connects with processor 1010 via Point-to-Point (PtP or P-P) interfaces 1017 and 1022. Either of these PtP embodiments may be achieved using a EMIB-backside trace containing embodiment as set forth in this disclosure. The chipset 1020 enables the processor 1010 to connect to other elements in a EMIB-backside trace containing embodiment in a system 1000. In an embodiment, interfaces 1017 and 1022 operate in accordance with a PtP communication protocol such as the Intel® QuickPath Interconnect (QPI) or the like. In other embodiments, a different interconnect may be used.

In an embodiment, the chipset 1020 is operable to communicate with the processor 1010, 1005N, the display device 1040, and other devices 1072, 1076, 1074, 1060, 1062, 1064, 1066, 1077, etc. The chipset 1020 may also be coupled to a wireless antenna 1078 to communicate with any device configured to at least do one of transmit and receive wireless signals.

The chipset 1020 connects to the display device 1040 via the interface 1026. The display 1040 may be, for example, a liquid crystal display (LCD), a plasma display, cathode ray tube (CRT) display, or any other form of visual display device. In an embodiment, the processor 1010 and the chipset 1020 are merged into a EMIB-backside trace containing embodiment in a system. Additionally, the chipset 1020 connects to one or more buses 1050 and 1055 that interconnect various elements 1074, 1060, 1062, 1064, and 1066. Buses 1050 and 1055 may be interconnected together via a bus bridge 1072 such as at least one EMIB-backside trace containing embodiment. In an embodiment, the chipset 1020, via interface 1024, couples with a non-volatile memory 1060, a mass storage device(s) 1062, a keyboard/mouse 1064, a network interface 1066, smart TV 1076, and the consumer electronics 1077, etc.

In an embodiment, the mass storage device 1062 includes, but is not limited to, a solid state drive, a hard disk drive, a universal serial bus flash memory drive, or any other form of computer data storage medium. In one embodiment, the network interface 1066 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 10 are depicted as separate blocks within the EMIB-backside trace containing embodiments in a computing system 1000, the functions performed by some of these blocks may be integrated within a single semiconductor circuit or may be implemented using two or more separate integrated circuits. For example, although cache memory 1016 is depicted as a separate block within processor 1010, cache memory 1016 (or selected aspects of 1016) can be incorporated into the processor core 1012.

To illustrate the a EMIB-backside trace containing embodiments and methods disclosed herein, a non-limiting list of examples is provided herein:

Example 1 is a semiconductive device, comprising: metallization on a first surface of a semiconductive substrate; a trace on a backside surface of the semiconductive substrate; and a ridge between the backside surface and a sidewall of the semiconductive substrate, wherein the trace also contacts the semiconductive substrate adjacent the ridge.

In Example 2, the subject matter of Example 1 optionally includes wherein the trace is a first trace; further including: a subsequent trace on the backside surface; and wherein the subsequent trace also contacts the semiconductive substrate adjacent the ridge.

In Example 3, the subject matter of any one or more of Examples 1-2 optionally include a subsequent semiconductive device on the first surface.

In Example 4, the subject matter of any one or more of Examples 1-3 optionally include wherein the trace also contacts the ridge.

In Example 5, the subject matter of any one or more of Examples 1-4 optionally include wherein the trace also contacts the ridge, and wherein the trace contacts the first surface.

In Example 6, the subject matter of any one or more of Examples 1-5 optionally include wherein the semiconductive device is a first bridge device, further including: a subsequent bridge device on the first surface; and wherein the trace also contacts the ridge and the first surface.

In Example 7, the subject matter of any one or more of Examples 1-6 optionally include wherein the semiconductive device is a first bridge device, further including: a subsequent bridge device above the first surface; wherein the trace also contacts the ridge and the first surface; and a printed wiring plane on the first surface, wherein the subsequent bridge device is on the printed wiring plane.

In Example 8, the subject matter of any one or more of Examples 1-7 optionally include wherein the bridge device is embedded in a semiconductor package substrate, and wherein the trace is coupled to a power plane in the semiconductor package substrate; further including: a first semiconductive device on a die side of the semiconductor package substrate; a first interconnect via contacting the first semiconductive device and the metallization; a subsequent interconnect via contacting the metallization on the first surface; and a subsequent semiconductive device on the die side, wherein the subsequent interconnect via is also coupled to the subsequent semiconductive device.

Example 9 is a semiconductor device package comprising: a semiconductive substrate embedded in a semiconductor package substrate, the semiconductive substrate including: metallization on a first surface; and a trace on a backside surface; a power plane within the semiconductor package substrate that is coupled to the trace by contact with an electrical bump; and an interconnect via contacting the metallization on the first surface.

In Example 10, the subject matter of Example 9 optionally includes wherein the semiconductive substrate further includes a ridge between the backside surface and a sidewall, wherein the trace also contacts the semiconductive substrate adjacent the ridge.

In Example 11, the subject matter of Example 10 optionally includes a first semiconductive device on a die side of the semiconductor package substrate, wherein the interconnect via is a first interconnect via, and wherein the first interconnect via is also coupled to the first semiconductive device; a subsequent interconnect via contacting the metallization on the first surface; and a subsequent semiconductive device on the die side, wherein the subsequent interconnect via is also coupled to the subsequent semiconductive device.

In Example 12, the subject matter of any one or more of Examples 10-11 optionally include an inductor coil embedded in the semiconductor package substrate, wherein the inductor coil is coupled to a bond pad on a land side of the semiconductor package substrate; and a passive device on the land side.

In Example 13, the subject matter of any one or more of Examples 10-12 optionally include an inductor coil embedded in the semiconductor package substrate, wherein the inductor coil is coupled to a bond pad on a land side of the semiconductor package substrate; a passive device coupled to the inductor coil and contacting the bond pad; and an electrical bump on the land side.

Example 14 is a semiconductor device package comprising: a first bridge device embedded in a semiconductor package substrate, the first bridge device including: a first surface; a trace on a backside surface; and a ridge between the backside surface and a sidewall, wherein the trace also contacts the ridge and the first surface; a power plane within the semiconductor package substrate that is coupled to the trace by contact with an electrical bump; an interconnect via contacting the trace; a subsequent bridge device above the first surface, wherein the subsequent bridge device is also embedded in the semiconductor package substrate; and an interconnect via contacting the subsequent bridge device.

In Example 15, the subject matter of Example 14 optionally includes a metallization layer on the first surface, wherein the subsequent bridge device is on the metallization layer.

In Example 16, the subject matter of Example 15 optionally includes wherein the metallization layer comprises one or more metal layers, further including a ground Vss plane, a power (Vcc) plane or a plurality of signal traces.

In Example 17, the subject matter of any one or more of Examples 14-16 optionally include a metallization layer on the first surface, wherein the subsequent bridge device is on the metallization layer; a first semiconductive device on a die side of the semiconductor package substrate, wherein the interconnect via is a first interconnect via, and wherein the first interconnect via is also coupled to the first semiconductive device; a subsequent interconnect via contacting the metallization layer on the first surface; and a subsequent semiconductive device on the die side, wherein the subsequent interconnect via is also coupled to the subsequent semiconductive device.

In Example 18, the subject matter of any one or more of Examples 14-17 optionally include a metallization layer on the first surface, wherein the subsequent bridge device is on the metallization layer; a first semiconductive device on a die side of the semiconductor package substrate, wherein the interconnect via is a first interconnect via, and wherein the first interconnect via is also coupled to the first semiconductive device; a subsequent interconnect via contacting the metallization layer on the first surface; a subsequent semiconductive device on the die side, wherein the subsequent interconnect via is also coupled to the subsequent semiconductive device; an inductor coil embedded in the semiconductor package substrate, wherein the inductor coil is coupled to a bond pad on a land side of the semiconductor package substrate; and a passive device on the land side.

In Example 19, the subject matter of any one or more of Examples 14-18 optionally include a metallization layer on the first surface, wherein the subsequent bridge device is on the metallization layer; a first semiconductive device on a die side of the semiconductor package substrate, wherein the interconnect via is a first interconnect via, and wherein the first interconnect via is also coupled to the first semiconductive device; a subsequent interconnect via contacting the metallization layer on the first surface; a subsequent semiconductive device on the die side, wherein the subsequent interconnect via is also coupled to the subsequent semiconductive device; an inductor coil embedded in the semiconductor package substrate, wherein the inductor coil is coupled to a bond pad on a land side of the semiconductor package substrate; a passive device coupled to the inductor coil and contacting the bond pad; and an electrical bump on the land side.

Example 20 is a process of assembling a semiconductor device package, comprising: forming a trace on a backside of a bridge die, wherein the bridge die includes a metallization layer on a first surface; embedding the bridge die in a semiconductor package substrate to couple the trace to a power plane in the semiconductor package substrate; and coupling an interconnect via in the semiconductor package substrate to the metallization layer.

In Example 21, the subject matter of Example 20 optionally includes forming an inductor coil in the semiconductor package substrate, wherein the inductor coil is coupled to a bond pad on a land side of the semiconductor package substrate.

In Example 22, the subject matter of any one or more of Examples 20-21 optionally include seating a first semiconductive device on a die side of the semiconductor package substrate, wherein the interconnect via is a first interconnect via, and wherein the first interconnect via is also coupled to the first semiconductive device; seating a subsequent semiconductive device on the die side, wherein the subsequent interconnect via is also coupled to the subsequent semiconductive device; and coupling a subsequent interconnect via to the subsequent semiconductive device.

In Example 23, the subject matter of any one or more of Examples 20-22 optionally include seating a first semiconductive device on a die side of the semiconductor package substrate, wherein the interconnect via is a first interconnect via, and wherein the first interconnect via is also coupled to the first semiconductive device; seating a subsequent semiconductive device on the die side, wherein the subsequent interconnect via is also coupled to the subsequent semiconductive device; coupling a subsequent interconnect via to the subsequent semiconductive device; forming an inductor coil in the semiconductor package substrate, wherein the inductor coil is coupled to a bond pad on a land side of the semiconductor package substrate.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electrical device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosed embodiments should be determined with reference to the appended claims, along with the full scope of equivalents to which such claims are entitled.

1. A semiconductive device, comprising:
metallization on a first surface of a semiconductive substrate;
a trace on a backside surface of the semiconductive substrate; and
a ridge between the backside surface and a sidewall of the semiconductive substrate, wherein the trace also contacts the semiconductive substrate adjacent the ridge.

2. The semiconductive device of claim 1, wherein the trace is a first trace; further including:
a subsequent trace on the backside surface; and
wherein the subsequent trace also contacts the semiconductive substrate adjacent the ridge.

3. The semiconductive device of claim 1, further including a subsequent semiconductive device on the first surface.

4. The semiconductive device of claim 1, wherein the trace also contacts the ridge.

5. The semiconductive device of claim 1, wherein the trace also contacts the ridge, and wherein the trace contacts the first surface.

6. The semiconductive device of claim 1, wherein the semiconductive device is a first bridge device, further including:
a subsequent bridge device on the first surface; and
wherein the trace also contacts the ridge and the first surface.

7. The semiconductive device of claim 1, wherein the semiconductive device is a first bridge device, further including:
a subsequent bridge device above the first surface;
wherein the trace also contacts the ridge and the first surface; and
a printed wiring plane on the first surface, wherein the subsequent bridge device is on the printed wiring plane.

8. The semiconductive device of claim 1, wherein the bridge device is embedded in a semiconductor package substrate, and wherein the trace is coupled to a power plane in the semiconductor package substrate; further including:
a first semiconductive device on a die side of the semiconductor package substrate;
a first interconnect via contacting the first semiconductive device and the metallization;
a subsequent interconnect via contacting the metallization on the first surface; and
a subsequent semiconductive device on the die side, wherein the subsequent interconnect via is also coupled to the subsequent semiconductive device.

9. A semiconductor device package comprising:
a semiconductive substrate embedded in a semiconductor package substrate, the semiconductive substrate including:
metallization on a first surface; and
a trace on a backside surface;
a power plane within the semiconductor package substrate that is coupled to the trace by contact with an electrical bump; and
an interconnect via contacting the metallization on the first surface.

10. The semiconductor device package of claim 9, wherein the semiconductive substrate further includes a ridge between the backside surface and a sidewall, wherein the trace also contacts the semiconductive substrate adjacent the ridge.

11. The semiconductor device package of claim 10, further including:
a first semiconductive device on a die side of the semiconductor package substrate, wherein the interconnect via is a first interconnect via, and wherein the first interconnect via is also coupled to the first semiconductive device;
a subsequent interconnect via contacting the metallization on the first surface; and
a subsequent semiconductive device on the die side, wherein the subsequent interconnect via is also coupled to the subsequent semiconductive device.

12. The semiconductor device package of claim 10, further including:
an inductor coil embedded in the semiconductor package substrate, wherein the inductor coil is coupled to a bond pad on a land side of the semiconductor package substrate; and
a passive device on the land side.

13. The semiconductor device package of claim 10, further including:
an inductor coil embedded in the semiconductor package substrate, wherein the inductor coil is coupled to a bond pad on a land side of the semiconductor package substrate;
a passive device coupled to the inductor coil and contacting the bond pad; and
an electrical bump on the land side.

14. A semiconductor device package comprising:
a first bridge device embedded in a semiconductor package substrate, the first bridge device including:
a first surface;
a trace on a backside surface; and
a ridge between the backside surface and a sidewall, wherein the trace also contacts the ridge and the first surface;
a power plane within the semiconductor package substrate that is coupled to the trace by contact with an electrical bump;
an interconnect via contacting the trace;
a subsequent bridge device above the first surface, wherein the subsequent bridge device is also embedded in the semiconductor package substrate; and
an interconnect via contacting the subsequent bridge device.

15. The semiconductor device package of claim 14, further including a metallization layer on the first surface, wherein the subsequent bridge device is on the metallization layer.

16. The semiconductor device package of claim 15, wherein the metallization layer comprises one or more metal layers, further including a ground Vss plane, a power (Vcc) plane or a plurality of signal traces.

17. The semiconductor device package of claim 14, further including:
a metallization layer on the first surface, wherein the subsequent bridge device is on the metallization layer;
a first semiconductive device on a die side of the semiconductor package substrate, wherein the interconnect via is a first interconnect via, and wherein the first interconnect via is also coupled to the first semiconductive device;
a subsequent interconnect via contacting the metallization layer on the first surface; and
a subsequent semiconductive device on the die side, wherein the subsequent interconnect via is also coupled to the subsequent semiconductive device.

18. The semiconductor device package of claim 14, further including:
a metallization layer on the first surface, wherein the subsequent bridge device is on the metallization layer;
a first semiconductive device on a die side of the semiconductor package substrate, wherein the interconnect via is a first interconnect via, and wherein the first interconnect via is also coupled to the first semiconductive device;
a subsequent interconnect via contacting the metallization layer on the first surface;
a subsequent semiconductive device on the die side, wherein the subsequent interconnect via is also coupled to the subsequent semiconductive device;
an inductor coil embedded in the semiconductor package substrate, wherein the inductor coil is coupled to a bond pad on a land side of the semiconductor package substrate; and
a passive device on the land side.

19. The semiconductor device package of claim 14, further including:
a metallization layer on the first surface, wherein the subsequent bridge device is on the metallization layer;
a first semiconductive device on a die side of the semiconductor package substrate, wherein the interconnect via is a first interconnect via, and wherein the first interconnect via is also coupled to the first semiconductive device;
a subsequent interconnect via contacting the metallization layer on the first surface;
a subsequent semiconductive device on the die side, wherein the subsequent interconnect via is also coupled to the subsequent semiconductive device;
an inductor coil embedded in the semiconductor package substrate, wherein the inductor coil is coupled to a bond pad on a land side of the semiconductor package substrate;
a passive device coupled to the inductor coil and contacting the bond pad; and
an electrical bump on the land side.

20. A process of assembling a semiconductor device package, comprising:
forming a trace on a backside of a bridge die, wherein the bridge die includes a metallization layer on a first surface;
embedding the bridge die in a semiconductor package substrate to couple the trace to a power plane in the semiconductor package substrate; and
coupling an interconnect via in the semiconductor package substrate to the metallization layer.

21. The process of claim 20, further including:
forming an inductor coil in the semiconductor package substrate, wherein the inductor coil is coupled to a bond pad on a land side of the semiconductor package substrate.

22. The process of claim 20, further including:
seating a first semiconductive device on a die side of the semiconductor package substrate, wherein the interconnect via is a first interconnect via, and wherein the first interconnect via is also coupled to the first semiconductive device;
seating a subsequent semiconductive device on the die side, wherein the subsequent interconnect via is also coupled to the subsequent semiconductive device; and
coupling a subsequent interconnect via to the subsequent semiconductive device.

23. The process of claim 20, further including:
seating a first semiconductive device on a die side of the semiconductor package substrate, wherein the interconnect via is a first interconnect via, and wherein the first interconnect via is also coupled to the first semiconductive device;
seating a subsequent semiconductive device on the die side, wherein the subsequent interconnect via is also coupled to the subsequent semiconductive device;
coupling a subsequent interconnect via to the subsequent semiconductive device;
forming an inductor coil in the semiconductor package substrate, wherein the inductor coil is coupled to a bond pad on a land side of the semiconductor package substrate.
